(19) United States
(12) Patent Application Publication
(10) Pub. No.: US 2017/0018666 A1
(43) Pub. Date: Jan. 19, 2017

(54) FORMATION OF HOMOJUNCTION IN KESTERITE-BASED SEMICONDUCTORS

(71) Applicant: International Business Machines Corporation, Armonk, NY (US)

(72) Inventors: Talia S. Gershon, White Plains, NY (US); Oki Gunawan, Westwood, NJ (US); Richard A. Haight, Mahopac, NY (US); Jeehwan Kim, Los Angeles, CA (US)

(21) Appl. No.: 14/799,089

(22) Filed: Jul. 14, 2015

(51) Int. Cl. H01L 31/032; H01L 31/18; H01L 31/072; H01L 31/0224

(52) U.S. Cl. CPC H01L 31/0326; H01L 31/022425; H01L 31/022475; H01L 31/022483; H01L 31/022466; H01L 31/18; H01L 31/072

(57) ABSTRACT

Kesterite-based homojunction photovoltaic devices are provided. The photovoltaic devices include a p-type semiconductor layer including a copper-zinc-tin containing chalcogenide compound and an n-type semiconductor layer including a silver-zinc-tin containing chalcogenide compound having a crystalline structure the same as a crystalline structure the copper-zinc-tin containing chalcogenide compound.

### STATEMENT OF GOVERNMENT RIGHTS

This invention was made with Government support under Contract No.: DE-EE0006334 awarded by Department of Energy. The Government has certain rights in this invention.

### BACKGROUND

The present application relates to photovoltaic devices, and more particularly to formation of homojunction photovoltaic devices employing kesterite-based semiconductors.

Kesterite-type semiconductors such as, for example, Cu₂ZnSn(S,Se)₄ (CZTSSe), have been developed as an alternative to higher cost, less available copper indium gallium selenide (CIGS) absorber materials for the next generation of thin film photovoltaic devices. CZTSSe and other related kesterite-type semiconductors consist of earth abundant and non-toxic elements, have band gap from 1.0 eV to 1.5 eV which are close to optimal band gaps for single-junction photovoltaic devices and large absorption coefficients greater than 10⁴ cm⁻¹, thus are promising absorber materials for thin film photovoltaic application.

CZTSSe absorber materials are naturally p-doped due to intrinsic defects, and thus behave as p-type semiconductors. When making photovoltaic devices, cadmium sulfide (CdS) is typically used as an n-type semiconductor layer injunction with a p-type CZTSSe absorber layer for charge separation. However, since CZTSSe and CdS have different crystalline structures, a heterogeneous p-n junction (i.e., heterojunction) is formed at an interface of the CZTSSe layer and the CdS layer. The presence of heterojunctions typically reduces the efficiency of the photovoltaic device due to the presence of high density defects at the interface.

In principle, photovoltaic devices having a lattice matched homojunction should have higher power conversion efficiency than photovoltaic devices having a lattice mismatched heterojunction. Therefore, there remains a need to develop kesterite-based homojunction photovoltaic devices.

### SUMMARY

The present application provides kesterite-based homojunction photovoltaic devices. The photovoltaic devices include a p-type semiconductor layer including a copper-zinc-tin containing chalcogenide compound and an n-type semiconductor layer including a silver-zinc-tin containing chalcogenide compound having a crystalline structure the same as a crystalline structure the copper-zinc-tin containing chalcogenide compound.

In one aspect of the present application, a photovoltaic device is provided. The photovoltaic device includes a substrate, a back contact layer present over the substrate, an absorber layer including a p-type chalcogenide compound present over the substrate, a buffer layer including an n-type chalcogenide compound present over the absorber layer, and a top contact layer present over the buffer layer. The p-type chalcogenide compound is represented by the formula: CuₓZn_{y}Sn_{z}(S_{q}Se_{1-q})₄, wherein x, y, and z range from 0 to 2, and 0≦q≦1_{y}. The n-type chalcogenide compound is represented by the formula: AgₓZn_{y}Sn_{z}(S_{q}Se_{1-q})₄, wherein x, y, and z range from 0 to 2, and 0≦q≦1_{y}.

In another aspect of the present application, a method of forming a photovoltaic device is provided. The method includes first forming a back contact layer over a substrate. An absorber layer is then formed over the substrate. The absorber layer comprises a p-type chalcogenide compound represented by the formula: CuₓZn_{y}Sn_{z}(S_{q}Se_{1-q})₄, wherein x, y, and z range from 0 to 2, and 0≦q≦1_{y}. Next, a buffer layer is formed over the absorber layer. The buffer layer includes an n-type chalcogenide compound represented by the formula: AgₓZn_{y}Sn_{z}(S_{q}Se_{1-q})₄, wherein x, y, and z range from 0 to 2, and 0≦q≦1_{y}. Next, a top contact layer is formed over the buffer layer.

In yet another aspect on the present application, a photovoltaic device is provided. The photovoltaic device includes a substrate, a back contact layer present over the substrate, an absorber layer including an n-type chalcogenide present over the absorber layer, a buffer layer including a p-type chalcogenide compound present over the absorber layer, a top contact interface layer present over the buffer layer, and a top contact layer present on the top contact interface layer. The n-type chalcogenide compound is represented by the formula: AgₓZn_{y}Sn_{z}(S_{q}Se_{1-q})₄, wherein x, y, and z range from 0 to 2, and 0≦q≦1_{y}. The p-type chalcogenide compound is represented by the formula: CuₓZn_{y}Sn_{z}(S_{q}Se_{1-q})₄, wherein x, y, and z range from 0 to 2, and 0≦q≦1_{y}.

### BRIEF DESCRIPTION OF SEVERAL VIEWS OF THE DRAWINGS

FIG. 1 is a cross-sectional view of a first exemplary photovoltaic device according to a first embodiment of the present application.

FIG. 2 is a flow diagram illustrating a method for forming the first exemplary photovoltaic device according to the first embodiment of the present application.

FIG. 3 is a cross-sectional view of a second exemplary photovoltaic device according to a second embodiment of the present application.

FIG. 4 is a flow diagram illustrating a method for forming the second exemplary photovoltaic device according to the first embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

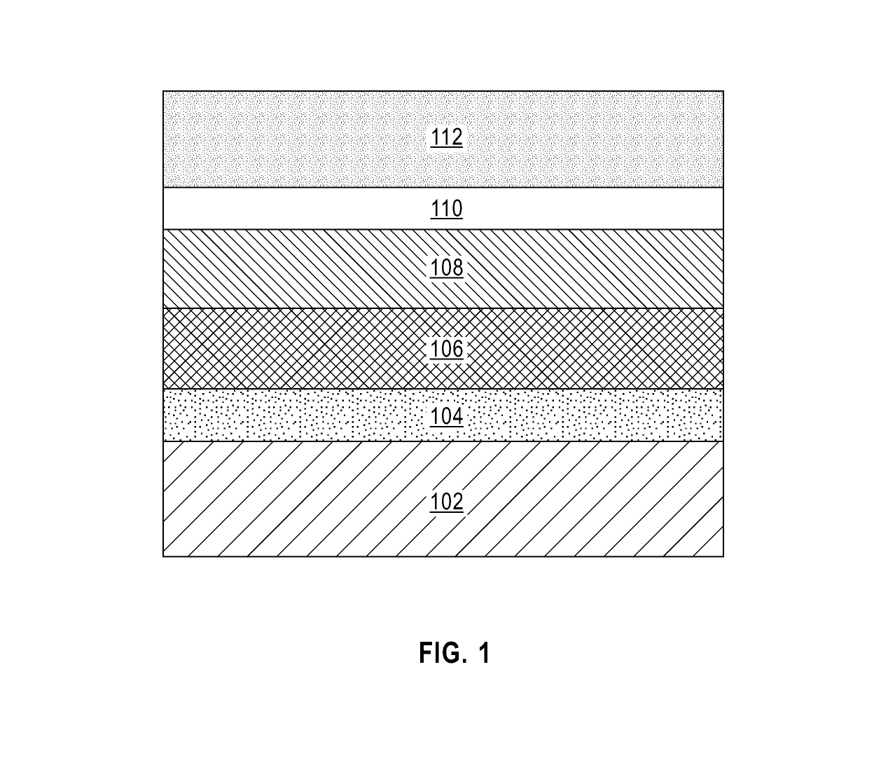

FIG. 1 illustrates a cross-sectional view of a first exemplary photovoltaic device according to a first embodiment of the present application. The first exemplary photovoltaic device includes a substrate 102 on which a multilayer thin-film stack is formed. The substrate 102 may be made of a glass, a polymer such as polyimide or polyester, a metal foil, or any other materials suitable for photovoltaic devices. The substrate 102 may have a thickness ranging from 10 μm to 5 mm, although lesser and greater thicknesses can also be employed.

The thin-film stack includes, from bottom to top, a back contact layer 104, an absorber layer 106, a buffer layer 108, a top contact interface layer 110, and a top contact layer 112.

The back contact layer 104 is formed on top of the substrate 102 and is made of an electrically conductive material that forms ohmic contact with the absorber layer 106. Exemplary electrically conductive materials that can be used as the back contact layer 104 include, but are not limited to, molybdenum (Mo), copper (Cu), aluminum (Al), titanium (Ti), nickel (Ni), niobium (Nb), tungsten (W), and chromium (Cr). The back contact layer 104 may be formed by any conventional deposition techniques including physical vapor deposition (PVD), evaporation, chemical vapor deposition (CVD), atomic layer deposition (ALD), plating, printing, or spin-coating. The back contact layer 104 that is formed may have a thickness from 300 nm to 2.0 μm, although lesser and greater thicknesses can also be employed. In one embodiment, the substrate 102 is a glass substrate and the back contact layer 104 is a layer of Mo.

The absorber layer 106 is formed on top of the back contact layer 104 and includes a copper-zinc-tin containing chalcogenide compound represented by the formula: CuₓZn_{y}Sn_{z}(S_{q}Se_{1-q})₄, wherein: x, y, and z range from 0 to 2, and 0≦q≦1 (hereinafter referred to as CZTSSe). In one embodiment, the Cu-Zn-Sn containing chalcogenide compound is Cu₂ZnSnSSe₄. Although the major elements in CZTSSe are Cu, Zn, Sn, S, and Se, the Cu—Zn—Sn containing chalcogenide compound also includes compositions that contain germanium (Ge) replacing some or all of the Sn. The Cu—Zn—Sn containing chalcogenide compound may also contain other dopants, including antimony (Sb), bismuth (Bi), sodium (Na), potassium (K), lithium (Li), and calcium (Ca).

The absorber layer 106 may be formed using a variety of techniques such as PVD, co-evaporation, in-line processing, plating, electroplating spin, printing, wet chemical deposition, or sol-gel processing. In one embodiment, the absorber layer 106 is formed using an evaporation approach. Suitable annealing approaches for forming a CZTSSe-based absorber layer are described, for example, in U.S. Pat. No. 8,617,915 to Guha et al., entitled “Annealing Thin Films”, the entire content of which is hereby incorporated by reference.

The buffer layer 108 is formed on top of the absorber layer 106 and includes a silver-zinc-tin containing chalcogenide compound represented by the formula: AgₓZn_{y}Sn_{z}(S_{q}Se_{1-q})₄, wherein: x, y, and z range from 0 to 2, and 0≦q≦1 (hereinafter referred to as AZTSSe). In one embodiment, the Ag—Zn—Sn containing chalcogenide compound is Ag₂ZnSnSSe₄. AZTSSe has a band gap ranging from 1.3 eV to 1.8 eV, depending on the S and/or Se ratio. The buffer layer 108 may be formed by co-evaporating or co-sputtering silver, zinc, tin, and sulfur or selenium at a temperature ranging from 350° C. to 375° C. under vacuum, and then optionally annealing the resulting film with a sulfur-containing (e.g., H₂S) and/or selenide-containing (e.g., H₂Se) vapor. The buffer layer 108 that is formed may have a thickness from 30 nm to 100 nm, although lesser and greater thicknesses can also be employed.

AZTSSe is an intrinsic n-type semiconductor and possesses a crystalline structure substantially identical to the crystalline structure of CZTSSe. In the present application, by employing a buffer layer containing an n-type AZTSSe which has a crystalline structure the same as that of the CZTSSe-containing absorber layer, a p-n homojunction is formed at the interface between the CZTSSe-containing absorber layer and the AZTSSe-containing buffer layer. In addition, since AZTSSe is grown at modest temperatures that may facilitate inter-diffusion, a better junction interface may be obtained. As a result, defects at the interface between the absorber layer and the buffer layer would be reduced and the efficiency of the photovoltaic device would increase. Moreover, and since AZTSSe has a slightly larger band gap than the band gap of CZTSSe, a photovoltaic device with a graded band gap can be formed, which leads to a further increase of the efficiency of the photovoltaic device.

The top contact interface layer 110 is formed on top of the buffer layer 108. The top contact interface layer 110 may include an intrinsic zinc oxide (ZnO). The top contact interface layer 110 makes the photovoltaic device less sensitive to lateral non-uniformities caused by differences in composition or defect concentration in the absorber and/or buffer layers 106, 108. The top contact interface layer 110 may be formed by PVD, CVD, sputtering, plating or printing. The top contact interface layer 110 that is formed may have a thickness from 5 nm to 150 nm, although lesser and greater thicknesses can also be employed. The top contact interface layer 110 is optional and can be omitted in some embodiments of the present application.

The top contact layer 112 is formed on top of the top contact interface layer 110, if present, or top of the buffer layer 108. The top contact layer 112 may include a transparent conductive oxide such as, for example, indium tin oxide (ITO), aluminum doped zinc oxide (AZO), fluorine doped tin oxide (FTO) or boron doped zinc oxide (BZO). The top contact layer 112 may be deposited by PVD, sputtering or CVD. The top contact layer 112 that is formed may have a thicknesses from 100 nm to 1000 nm, although lesser and greater thicknesses can also be employed.

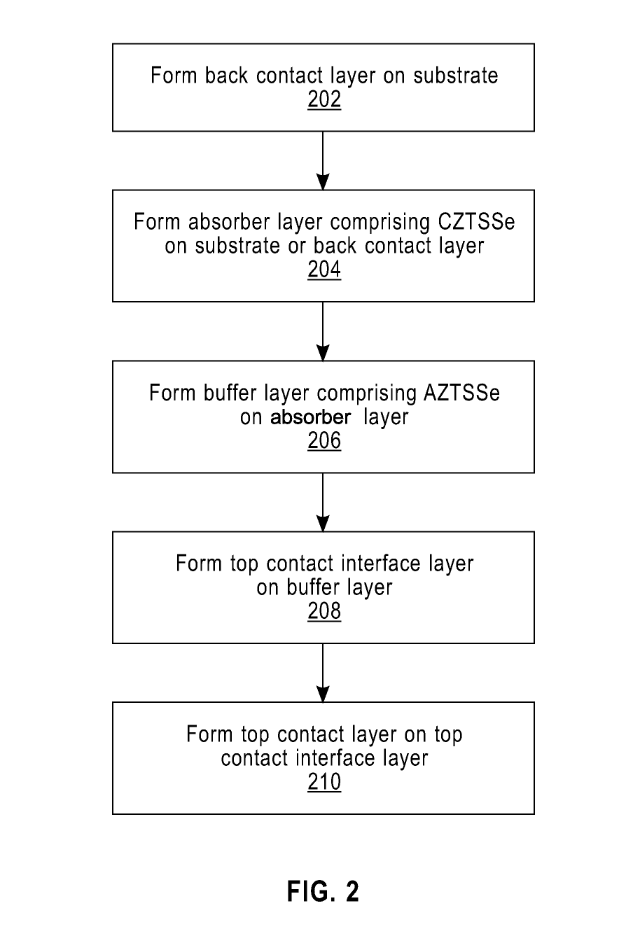

FIG. 2 is a flow diagram illustrating a method for forming the first exemplary photovoltaic device according to the first embodiment of the present application. In block 202, a back contact layer is deposited on a substrate. In block 204, an absorber layer including a copper-zinc-tin containing chalcogenide compound represented by the formula: CuₓZn_{y}Sn_{z}(S_{q}Se_{1-q})₄, wherein: x, y, and z range from 0 to 2, and 0≦q≦1, is formed on the back contact layer. In block 206, a buffer layer including a silver-zinc-tin containing chalcogenide compound represented by the formula: AgₓZn_{y}Sn_{z}(S_{q}Se_{1-q})₄, wherein: x, y, and z range from 0 to 2, and 0≦q≦1, is formed on the absorber layer. In block 208, a top contact interface layer is formed on the buffer layer. In block 210, a top contact layer is formed on the top contact interface layer.

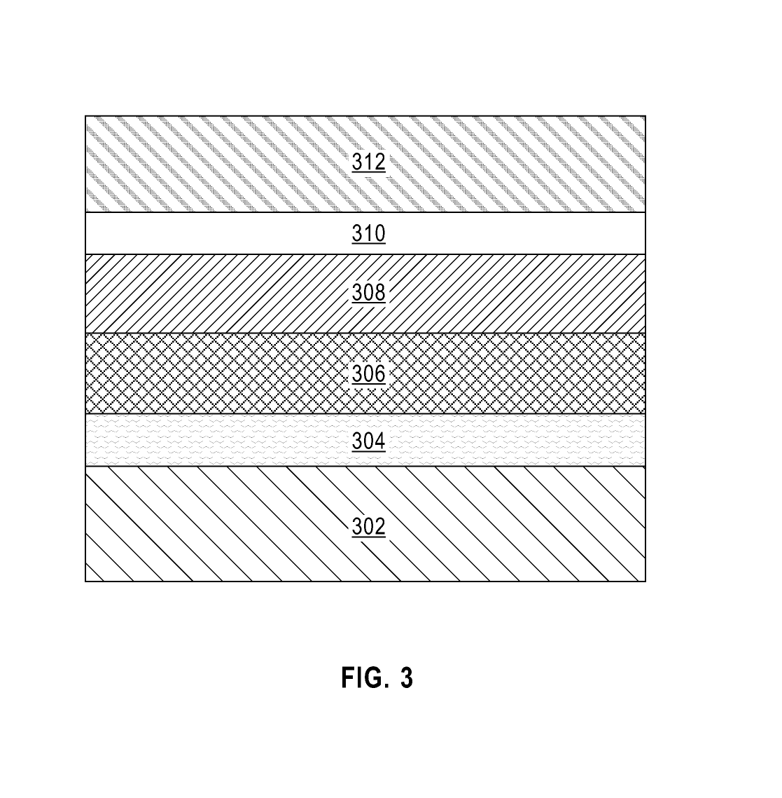

FIG. 3 illustrates a cross-sectional view of a second exemplary photovoltaic device according to a second embodiment of the present application. The second exemplary photovoltaic device includes a substrate 302 on which a multilayer thin-film stack is formed. The substrate 302 may be made of a glass, a polymer such as polyimide or polyester, a metal foil, or any other materials suitable for photovoltaic devices. The substrate 302 may have a thickness ranging from 10 μm to 5 mm, although lesser and greater thicknesses can also be employed.

The thin-film stack includes, from bottom to top, a back contact layer 304, an absorber layer 306, a buffer layer 308, a top contact interface layer 310, and a top contact layer 312. In the second embodiment of the present application, an n-type AZTSSe is employed as an absorber layer, while a p-type CZTSSe is employed as the buffer layer to form a p-n homojunction therebetween.

The back contact layer 304 may include a low work function metal oxide with a work function lower than 4.4 eV. The back contact layer 304 may include a fluorine doped tin oxide (FTO) or a FTO coated with a metal oxide such as, for example, gallium oxide (Ga₂O₃), titanium oxide (TiO₂), tin oxide (SnO₂), or ZnO. The back contact layer 304 may be formed by PVD, sputtering, evaporation, CVD or ALD. The back contact layer 304 that is formed may have a thickness from 300 nm to 1.0 μm, although lesser and greater thicknesses can also be employed.

The absorber layer 306 is formed on top of the back contact layer 304 and includes a silver-zinc-tin containing chalcogenide compound represented by the formula: AgₓZn_{y}Sn_{z}(SqSe_{1-q})₄, wherein: x, y, and z range from 0 to 2, and 0≦w≦1. The compositions, processing techniques and thickness ranges described above for the AZTSSe-containing buffer layer 108 in FIG. 1 are also applicable here.

The buffer layer 308 is formed on top of the absorber layer 306 and includes a copper-zinc-tin containing chalcogenide compound represented by the formula: CuₓZn_{y}Sn_{z}(S_{q}Se_{1-q})₄, wherein: x, y, and z range from 0 to 2, and 0≦q≦1. The compositions, processing techniques and thickness ranges described above for the CZTSSe-containing absorber layer 106 in FIG. 1 are also applicable here.

The top contact interface layer 310 is formed on top of the buffer layer 308 and includes a high work function metal oxide with a work function greater than 4.8 eV. The top contact interface layer 310 acts as a hole collecting layer and allows for tuning the work function of the overlying top contact layer 312. Exemplary high work function oxides include, but are not limited to, tungsten oxide (WO₃), vanadium oxide (V₂O₅), molybdenum oxide (MoO₃), and nickel oxide (NiO). The top contact interface layer 310 may be deposited by PVD or CVD. The top contact interface layer 310 that is formed may have a thicknesses from 20 nm to 100 nm, although lesser and greater thicknesses can also be employed.

The top contact layer 312 is formed on top of the top contact interface layer 310 and includes a high work function metal such as gold (Au), platinum (Pt), or palladium (Pd), or a high work functional metal oxide such as ITO. The top contact layer 312 may be deposited by PVD, sputtering or CVD. The top contact layer 312 that is formed may have a thicknesses from 100 nm to 1000 nm, although lesser and greater thicknesses can also be employed.

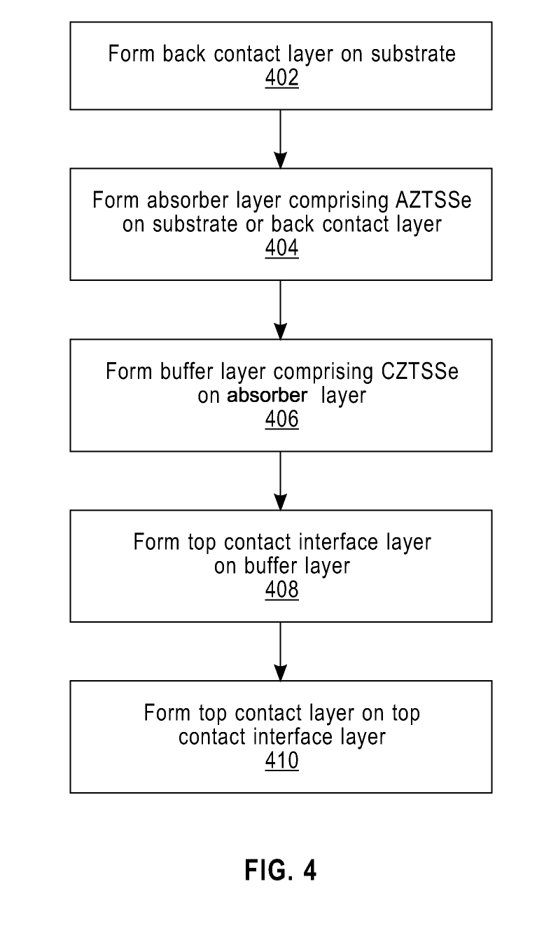

FIG. 4 is a flow diagram illustrating a method for forming the second exemplary photovoltaic device according to the second embodiment of the present application. In block 402, a back contact layer is deposited on a substrate. In block 404, an absorber layer including a silver-zinc-tin containing chalcogenide compound represented by the formula: AgₓZn_{y}Sn_{z}(S_{q}Se_{1-q})₄, wherein: x, y, and z range from 0 to 2, and 0≦q≦1, is formed on the back contact layer. In block 406, a buffer layer including a copper-zinc-tin containing chalcogenide compound represented by the formula: CuₓZn_{y}Sn_{z}(S_{q}Se_{1-q})₄, wherein: x, y, and z range from 0 to 2, and 0≦q≦1, is formed on the absorber layer. In block 408, a top contact interface layer is formed on the buffer layer. In block 410, a top contact layer is formed on the top contact interface layer.

While the application has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the application is intended to encompass all such alternatives, modifications and variations which fall within the scope and spirit of the application and the following claims.

1. A photovoltaic device comprising:
a substrate;
a back contact layer present over the substrate;
an absorber layer comprising a p-type chalcogenide compound present over the substrate, wherein the p-type chalcogenide compound is represented by the formula: CuₓZn_{y}Sn_{z}(S_{q}Se_{1-q})₄, wherein: x, y, and z independently range from 0 to 2, and 0≦q≦1;
a buffer layer comprising an n-type chalcogenide compound present over the absorber layer, wherein the n-type chalcogenide compound is represented by the formula: AgₓZn_{y}Sn_{z}(S_{q}Se_{1-q})₄, wherein: x, y, and z independently range from 0 to 2, and 0≦q≦1; and
a top contact layer present over the buffer layer.

2. The photovoltaic device of claim 1, wherein the absorber layer comprises Cu₂ZnSnSe₄.

3. The photovoltaic device of claim 1, wherein the buffer layer comprises Ag₂ZnSnSe₄.

4. The photovoltaic device of claim 1, wherein the p-type chalcogenide compound has a crystalline structure the same as a crystalline structure of the n-type chalcogenide compound.

5. The photovoltaic device of claim 1, wherein the substrate is a glass substrate, and the back contact layer is a layer of molybdenum (Mo).

6. The photovoltaic device of claim 1, wherein the top contact layer comprises indium tin oxide (ITO), aluminum doped zinc oxide (AZO), fluorine doped tin oxide (FTO), or boron doped zinc oxide (BZO).

7. The photovoltaic device of claim 1, further comprising a top contact interface layer present between the buffer layer and the top contact layer, wherein the top contact interface layer comprises an intrinsic zinc oxide (ZnO).

8. A method of forming a photovoltaic device comprising
forming a back contact layer over a substrate;
forming an absorber layer over the substrate, the absorber layer comprising a p-type chalcogenide compound represented by the formula: CuₓZn_{y}Sn_{z}(S_{q}Se_{1-q})₄, wherein: x, y, and z independently range from 0 to 2, and 0≦q≦1;
forming a buffer layer over the absorber layer, the buffer layer comprising an n-type chalcogenide compound represented by the formula: AgₓZn_{y}Sn_{z}(S_{q}Se_{1-q})₄, wherein: x, y, and z independently range from 0 to 2, and 0≦q≦1; and
forming a top contact layer over the buffer layer.

9. The method of claim 8, wherein the forming the buffer layer comprises:
co-evaporating or co-sputtering silver, zinc, tin, and sulfur or selenium at a temperature ranging from 350° C. to 375° C.

10. The method of claim 9, further comprising annealing the buffer layer with a sulfur-containing and/or selenide-containing vapor.

11. The method of claim 8, wherein the absorber layer comprises Cu₂ZnSnSe₄, and wherein the buffer layer comprises Ag₂ZnSnSe₄.

12. The method of claim 8, wherein the absorber layer has a crystalline structure the same as a crystalline structure of the buffer layer.

13. The method of claim 8, wherein the substrate is a glass substrate, and the back contact layer is a layer of molybdenum (Mo).

14. The method of claim 8, wherein the top contact layer comprises indium tin oxide (ITO), aluminum doped zinc oxide (AZO), fluorine doped tin oxide (FTO), or boron doped zinc oxide (BZO).

15. The method of claim 8, further comprising forming a top contact interface layer on the buffer layer prior to the forming the top contact layer, wherein the top contact interface layer comprises an intrinsic zinc oxide (ZnO).

16. A photovoltaic device comprising:
a substrate;
a back contact layer present over the substrate;
an absorber layer comprising an n-type chalcogenide present over the absorber layer, wherein the n-type chalcogenide compound is represented by the formula: AgₓZn_{y}Sn_{z}(S_{q}Se_{1-q})₄, wherein: x, y, and z independently range from 0 to 2, and 0≦q≦1;
a buffer layer comprising a p-type chalcogenide compound present over the absorber layer, wherein the p-type chalcogenide compound is represented by the formula: CuₓZn_{y}Sn_{z}(S_{q}Se_{1-q})₄, wherein: x, y, and z independently range from 0 to 2, and 0≦q≦1;
a top contact interface layer present over the buffer layer; and
a top contact layer present on the top contact interface layer.

17. The photovoltaic device of claim 16, wherein the p-type chalcogenide compound has a crystalline structure the same as a crystalline structure of the n-type chalcogenide compound.

18. The photovoltaic device of claim 16, wherein the back contact layer comprises a fluorine doped tin oxide (FTO) or a FTO coated with a metal oxide selected from gallium oxide (Ga₂O₃), titanium oxide (TiO₂), tin oxide (SnO₂), and zinc oxide (ZnO).

19. The photovoltaic device of claim 16, wherein the top contact interface layer comprises tungsten oxide (WO₃), vanadium oxide (V₂O₅), molybdenum oxide (MoO₃), or nickel oxide (NiO).

20. The photovoltaic device of claim 16, wherein the top contact layer comprises gold (Au), platinum (Pt), palladium (Pd), or indium tin oxide (ITO).
